(19) United States
(12) Patent Application Publication
(10) Pub. No.: US 2018/0315944 A1
(43) Pub. Date: Nov. 1, 2018

(54) METHOD OF RESTORING BRIGHT DOT OF ORGANIC ELECTROLUMINESCENT DEVICE, ORGANIC ELECTROLUMINESCENT DEVICE AND MANUFACTURING METHOD THEREOF, AND DISPLAY APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventors: Qun MA, Beijing (CN); Tie WANG, Beijing (CN); Ning AO, Beijing (CN); Jianqiang WANG, Beijing (CN); Haizhi XIU, Beijing (CN); Jin XU, Beijing (CN)

(21) Appl. No.: 15/845,670

(22) Filed: Dec. 18, 2017

(30) Foreign Application Priority Data
Apr. 28, 2017 (CN) 201710297634.1

(51) Int. Cl. H01L 51/50; H01L 21/66; H01L 51/56

(52) U.S. Cl. CPC H01L 51/5096; H01L 22/20; H01L 51/004; H01L 2251/568; H01L 51/56

(57) ABSTRACT

The disclosure provides a method of restoring a bright dot of an organic electroluminescent device, an organic electroluminescent device and a manufacturing method thereof, and a display apparatus. The method of restoring the bright dot of the organic electroluminescent device comprises blocking transmission of holes or electrons in the sub-pixel unit corresponding to the bright dot. By blocking transmission of holes or electrons in the sub-pixel unit corresponding to the bright dot, it is possible to block a flow of current towards an organic functional layer in the sub-pixel unit corresponding to the bright dot such that the sub-pixel unit will not emit light, thus converting the bright dot into a dark dot.

### CROSS REFERENCE TO RELATED APPLICATION

This application claims priority to and the benefit of Chinese Patent Application No. 201710297634.1 filed on Apr. 28, 2017, the disclosure of which is incorporated herein in its entirety by reference.

### TECHNICAL FIELD

The disclosure relates to a method of restoring a bright dot of an organic electroluminescent device, an organic electroluminescent device and a manufacturing method thereof, and a display apparatus.

### BACKGROUND

During the manufacture of organic electroluminescent devices (OLEDs), bright dot badness is always a key factor that restricts a yield rate of OLED products. During the manufacture of OLEDs, the bright dot badness is a badness that has an extremely high incidence due to process, environment or other factors. The presence of the bright dots directly decreases a grade of the product. If the number of the bright dots exceeds a certain number, the display panel will be directly scrapped. This increases the cost while wasting human and material resources.

### SUMMARY

In one aspect of the disclosure, the disclosure provides a method of restoring a bright dot of an organic electroluminescent device. According to an embodiment of unit corresponding to the bright dot.

According to the embodiment of the disclosure, the blocking transmission of holes or electrons in the sub-pixel unit corresponding to the bright dots is implemented by insulation between a first electrode and an organic functional layer in the sub-pixel unit corresponding to the bright dot.

According to the embodiment of the disclosure, the step of blocking comprises: determining a coordinate of the sub-pixel unit corresponding to the bright dot on a base, wherein the base comprises a substrate and a first electrode arranged on a side of the substrate; forming an insulating layer at a position corresponding to the coordinate, the insulating layer covering the first electrode.

According to the embodiment of the disclosure, the coordinate of the sub-pixel unit corresponding to the bright dot is determined by automatic optical inspection.

According to the embodiment of the disclosure, a material that forms the insulating layer comprises polyimide.

In another aspect of the disclosure, the disclosure provides a method of manufacturing the organic electroluminescent device. According to an embodiment of the disclosure, the method comprises a step of restoring a bright dot using the aforementioned method.

According to the embodiment of the disclosure, the step of restoring comprises: forming a first electrode on a substrate to obtain a base; determining a coordinate of a sub-pixel unit corresponding to the bright dot on the base; forming an insulating layer at a position corresponding to the coordinate, the insulating layer covering the first electrode; forming an organic functional layer and a second electrode in sequence on a side of the first electrode and the insulating layer far away from the substrate.

In another aspect of the disclosure, the disclosure provides an organic electroluminescent device. According to an embodiment of the disclosure, the organic electroluminescent device is manufactured by the aforementioned method.

In another aspect of the disclosure, the disclosure provides an organic electroluminescent device. According to an embodiment of the disclosure, the organic electroluminescent device comprises: a first electrode; a second electrode arranged opposite to the first electrode; an organic functional layer arranged between the first electrode and the second electrode, wherein in a sub-pixel unit corresponding to a bright dot, an insulating layer is further arranged between the first electrode and the organic functional layer.

In another aspect of the disclosure, the disclosure provides a display apparatus. According to an embodiment of the disclosure, the display apparatus comprises the aforementioned organic electroluminescent device.

### BRIEF DESCRIPTION OF THE DRAWINGS

FIG. 1 illustrates a structural schematic diagram of a base according to an exemplary embodiment of the disclosure.

FIG. 2 illustrates a flow schematic diagram of a method of restoring a bright dot of an organic electroluminescent device according to an exemplary embodiment of the disclosure.

FIGS. 3A-3C illustrate a flow schematic diagram of forming an insulating layer according to an exemplary embodiment of the disclosure.

FIG. 4 illustrates a flow schematic diagram of the method of manufacturing an organic electroluminescent device according to an exemplary embodiment of the disclosure.

FIG. 5 illustrates a structural schematic diagram of an organic electroluminescent device according to an exemplary embodiment of the disclosure.

FIG. 6 illustrates a structural schematic diagram of an organic electroluminescent device according to an exemplary embodiment of the disclosure.

### DETAILED DESCRIPTION

Embodiments of the disclosure are described below in details. The described embodiments below are exemplary and used only for explaining the disclosure, instead of being understood as a limit to the disclosure. Where any embodiment is not specified with technique or conditions, it is conducted in accordance with the technique or the conditions as described in the documents in the art or in accordance with the product description. Where any reagent or instrument is not specified with the manufacturer, it is a conventional product that may be purchased in the market.

As can be seen from the above, current bright dot badness still needs to be improved.

The disclosure is aimed at solving, at least to a certain extent, one of technical problems in the related art. For this reason, one object of the disclosure is to present a method of effectively restoring the bright dot of the organic electroluminescent device.

In one aspect of the disclosure, the disclosure provides a method of restoring the bright dot of the organic electroluminescent device. According to an embodiment of the disclosure, the method is to block transmission of holes or electrons in a sub-pixel unit corresponding to the bright dot. The inventor have found that, by blocking the transmission of the holes or the electrons in the sub-pixel unit corresponding to the bright dot, a flow of current towards an organic functional layer in the sub-pixel unit corresponding to the bright dot may be effectively blocked such that the sub-pixel unit will not emit light, thus converting the bright dot into a dark dot and effectively enhancing the display effect and quality of the organic electroluminescent device.

It should be noted that, the term “bright dot” used in the disclosure refers to a sub-pixel dot or a pixel dot that is always lighted in the organic electroluminescent device.

According to the embodiment of the disclosure, no special limits are made to the specific manner of blocking transmission of holes or electrons in the sub-pixel unit corresponding to the bright dot, as long as the current will not pass through the organic functional layer in the sub-pixel unit which thus will not emits the lights. In some embodiments of the disclosure, the adopted manner may be to form an insulating member on an arbitrary portion of the transmission path of the holes or the electrons such that the current will not flow towards the organic functional layer and thus the sub-pixel unit will not emit the lights. In some exemplary embodiments of the disclosure, the blocking transmission of the holes or the electrons in the sub-pixel unit corresponding to the bright dot is implemented by the insulation between the first electrode and the organic functional layer in the sub-pixel unit corresponding to the bright dot. Thus, the transmission of the holes may be effectively blocked such that the organic functional layer will not emit the lights, and thus the sub-pixel unit changes from a bright dot to a dark dot, the grade of the organic electroluminescent device is notably increased, and the display effect is significantly improved.

According to the embodiment of the disclosure, the aforementioned first electrode refers to one of electrodes capable of providing an applied voltage to the organic functional layer, which may be either a cathode or an anode. In some embodiments of the disclosure, the first electrode may be the anode.

According to the embodiment of the disclosure, referring to FIG. 2, the method of restoring the bright dot of the organic electroluminescent device may comprise the steps of:

S100: determining a coordinate of a sub-pixel unit corresponding to the bright dot on a base, wherein the base comprises a substrate and a first electrode arranged on a side of the substrate.

According to the embodiment of the disclosure, no special limits are made to the specific types of the substrate that can be adopted, and those skilled in the art may make a flexible selection as needed, for example, including but not limited to, a glass substrate, a polymer substrate, a ceramic substrate or a metal substrate.

According to the embodiment of the disclosure, no special limits are made to the material that forms the first electrode, as long as the need of electric conduction can be satisfied and a regular operation of the organic electroluminescent device can be guaranteed. In some embodiments of the disclosure, the material that forms the first electrode comprises, but is not limited to, a transparent conductive oxide (for example, indium tin oxide, zinc tin oxide, indium zinc oxide, aluminum-doped zinc oxide and so on), graphene, a carbon tube and so on. Thus, the conductive performance is good, and the display effect is better.

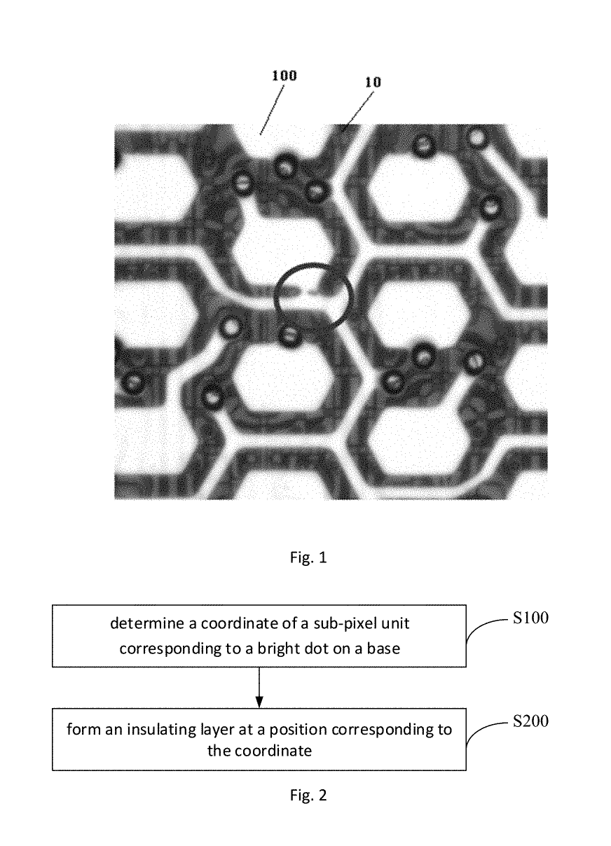

In addition, those skilled in the art may understand that, the first electrodes are arranged in an array on the substrate and correspond to a plurality of sub-pixel units, that is to say, each sub-pixel unit corresponds to one first electrode, which is not repeatedly described herein. Specifically, FIG. 1 illustrates a structural schematic diagram of the base in which there is the bad bright dot, comprising the substrate 100 and the first electrodes 10, wherein the circled position is the sub-pixel unit corresponding to the bright dot. Certainly, those skilled in the art may understand that, the distribution manner of the first electrodes on the substrate is not limited to the circumstance as shown in FIG. 1, as long as the display requirements of the organic electroluminescent device can be satisfied.

According to the embodiment of the disclosure, the bright dot badness of the pixel is generally caused by short circuit, insufficient tin, missing parts or other factors, and the automatic optical inspection (AOI) involves an apparatus that inspects common drawbacks confronted during the welding manufacture based on optical principles. The process of inspecting is as follows: when the automatic inspection is performed, the machine automatically scans the base and captures images using a camera, compares the inspected welding dot with the qualified parameters in the database, checks drawbacks in the base through image processing, and displays/marks the drawbacks by a display or an automatic flag. The AOI covers the following drawbacks or badness: solder paste printing: presence/absence, migration, insufficient tin, excessive tin, open circuit, continuous tin, contamination and so on; part drawbacks: missing parts, migration, skewed, made up, side against, turn piece, wrong thing, OCV, damaged, capacity polarity reversal and so on; weld joint drawbacks after crest weld and furnace: excessive tin, insufficient tin, empty solder, continuous tin, copper foil contamination and so on. Therefore, in some embodiments of the disclosure, the automatic optical inspection is used to determine a coordinate of the sub-pixel unit corresponding to the bright dot. Thus, the coordinate of the sub-pixel unit corresponding to the bright dot can be simply and rapidly inspected, the operation can be automated, human and material resources can be saved, and mass production can be easily achieved.

S200: forming an insulating layer at a position corresponding to the coordinate, the insulating layer covering the first electrode.

According to the embodiment of the disclosure, no special limits are made to the specific method of forming the insulating layer, and those skilled in the art may make a flexible selection as needed. In some embodiments of the disclosure, an insulating material is automatically injected into the position corresponding to the coordinate such that an insulating layer can be formed at the corresponding position by using an apparatus having a positioning function, or the insulating material is injected into the position corresponding to the coordinate so as to form the insulating layer by a manual operation. Thus, the operation is easy and convenient, and the control is easy.

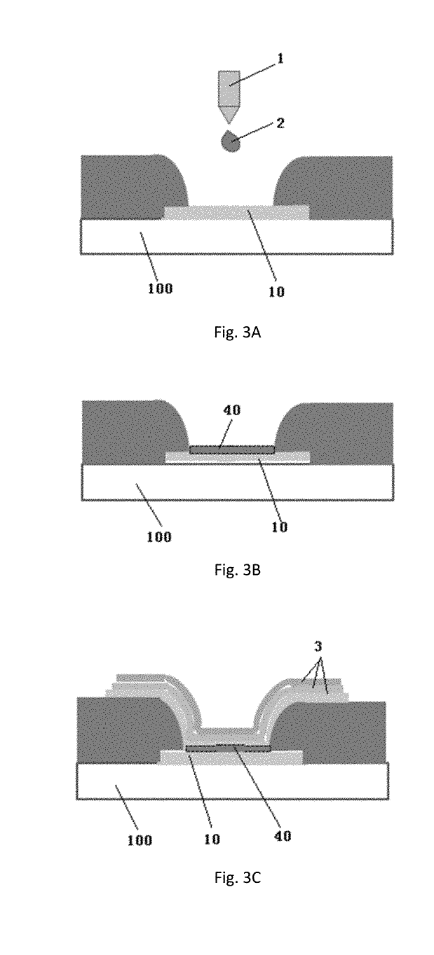

In the embodiment of the disclosure, referring to FIGS. 3A-3C, the formation of the insulating layer may comprise the steps of: directly aiming the apparatus 1 for injecting the insulating material 2 at a coordinate position (refer to FIG. 3A) of the sub-pixel unit corresponding to the bright dot, injecting the insulating material into the corresponding coordinate position, and then performing a bake to make the insulating material dry so as to form the insulating layer 40 (refer to FIG. 3B). Then, the formation may further comprise the step of forming other layer structures 3 of the organic electroluminescent device (refer to FIG. 3C) according to actual needs, for example, forming the other layer structures by a deposition method.

According to the embodiment of the disclosure, no special limits are made to the material that forms the insulating layer, as long as the transmission of the electrons or holes can be blocked, and those skilled in the art may make a flexible selection according to actual needs. In some embodiments of the disclosure, the material that forms the insulating layer may be any known insulating material. In some embodiments of the disclosure, the material that forms the insulating layer may comprise polyimide. Thus, the material source is wide, the cost is low, and the insulating effect is good.

The inventor has found that, after the bright dot is restored by the method, the bright dot is effectively converted into a dark dot in the organic electroluminescent device, and thus the quality control grade is notably increased and the display effect is significantly improved for the organic electroluminescent device. Specifically, the quality control grade of the organic electroluminescent device is ranked in accordance with the following table 1, and after the bright dot is restored by the method of the disclosure, the grade of the organic electroluminescent device may be raised from T/Q to A/T.

| Badness | S | A | T | Q |
|---|---|---|---|---|
| Bright Dot | N ≤ 0 | N ≤ 0 | N ≤ 2 | N ≤ 5 |
| Dark Dot | N ≤ 0 | N ≤ 1 | N ≤ 2 | N ≤ 5 |
| Bright Dot + | N ≤ 0 | N ≤ 1 | N ≤ 2 | N ≤ 5 |
| Dark Dot | | | | |
| 2 Neighboring | N ≤ 0 | N ≤ 0 | N ≤ 0 | N ≤ 4 |
| Dark Dots | | | | (2 groups) |
| 3 Neighboring | N ≤ 0 | N ≤ 0 | N ≤ 0 | N ≤ 3 |
| Dark Dots | | | | (1 group) |

In another aspect of the disclosure, the disclosure provides a method of manufacturing the organic electroluminescent device. According to the embodiment of the disclosure, the method comprises a step of restoring the bright dot using the aforementioned method. The inventor has found that, for the organic electroluminescent device as manufactured by the method, the number of bad bright dots is significantly reduced, the display effect and quality is notably improved, and the quality control grade is notably increased.

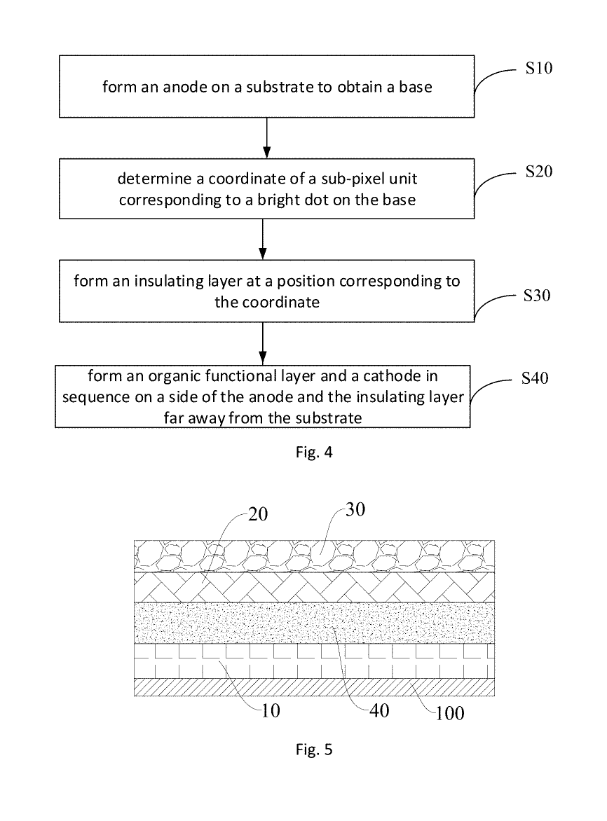

According to the embodiment of the disclosure, referring to FIG. 4, the method of manufacturing the organic electroluminescent device comprises the steps of:

S10: forming a first electrode on a substrate to obtain a base.

According to the embodiment of the disclosure, no special limits are made to the specific method of forming the first electrode in the step S10, and those skilled in the art may select any known method adapted to form the first electrode. In some embodiments of the disclosure, the method that can be adopted includes, but is not limited to, the physical vapor deposition, the chemical vapor deposition (for example, sputtering, evaporation, or other methods). Thus, the process is mature, the cost is low, the operation is simple and convenient, and the control is easy.

According to the embodiment of the disclosure, the types of the substrate that can be adopted and the material that forms the first electrode in the step S10 coincide with the above-described substrate and first electrode, and thus are not repeatedly described herein.

S20: determining a coordinate of the sub-pixel unit corresponding to the bright dot on a base.

According to the embodiment of the disclosure, the bright dot badness of the pixel is generally caused by short circuit, insufficient tin, missing parts or other factors, and the automatic optical inspection (AOI) involves an apparatus that inspects common drawbacks confronted during the welding manufacture based on optical principles. The process of inspecting is as follows: when the automatic inspection is performed, the machine automatically scans the base and captures images using a camera, compares the inspected welding dot with the qualified parameters in the database, checks drawbacks in the base through image processing, and displays/marks the drawbacks by a display or an automatic flag. The AOI covers the following drawbacks or badness: solder paste printing: presence/absence, migration, insufficient tin, excessive tin, open circuit, continuous tin, contamination and so on; part drawbacks: missing parts, migration, skewed, made up, side against, turn piece, wrong thing, OCV, damaged, capacity polarity reversal and so on; weld joint drawbacks after crest weld and furnace: excessive tin, insufficient tin, empty solder, continuous tin, copper foil contamination and so on. Therefore, in some embodiments of the disclosure, the automatic optical inspection is used to determine the coordinate of the sub-pixel unit corresponding to the bright dot. Thus, the coordinate of the sub-pixel unit corresponding to the bright dot can be simply and rapidly inspected, the operation can be automated, human and material resources can be saved, and mass production can be easily achieved.

S30: forming an insulating layer at a position corresponding to the coordinate, the insulating layer covering the first electrode.

According to the embodiment of the disclosure, no special limits are made to the specific method of forming the insulating layer, and those skilled in the art may make a flexible selection according to actual needs. In some embodiments of the disclosure, an insulating material is automatically injected into the position corresponding to the coordinate such that an insulating layer can be formed at the corresponding position by using an apparatus having a positioning function, or the insulating material is injected into the position corresponding to the coordinate so as to form an insulating layer by a manual operation. Thus, the operation is easy and convenient, and the control is easy.

According to the embodiment of the disclosure, no special limits are made to the material that forms the insulating layer, as long as the transmission of the holes or the electrons can be blocked, and those skilled in the art may make a flexible selection according to actual needs. In some embodiments of the disclosure, the material that forms the insulating layer may be any known insulating material. In some embodiments of the disclosure, the material that forms the insulating layer may comprise polyimide. Thus, the material source is wide, the cost is low, and the insulating effect is good.

S40: forming an organic functional layer and a second electrode in sequence on a side of the first electrode and the insulating layer far away from the substrate.

According to the embodiment of the disclosure, the aforementioned first electrode and second electrode are a pair of electrodes that may apply a voltage to the organic functional layer. The first electrode may be either a cathode or an anode, and accordingly the second electrode may be either an anode or a cathode. In some embodiments of the disclosure, the first electrode may be an anode, and accordingly the second electrode may be a cathode.

According to the embodiment of the disclosure, no special limits are made to the specific method of forming the organic functional layer and the second electrode, and those skilled in the art may make a flexible selection as needed. In some embodiments of the disclosure, a method that can be adopted includes, but is not limited to, the physical vapor deposition, the chemical vapor deposition (for example, sputtering, evaporation or other methods). Thus, the process is mature, the cost is low, the operation is simple and convenient, and the control is easy.

According to the embodiment of the disclosure, no special limits are made to the specific structure of the organic functional layer, and those skilled in the art may make a flexible selection as needed. In some embodiments of the disclosure, the organic functional layer may be formed only by the light emitting layer. In some other embodiments of the disclosure, in addition to the light emitting layer, the organic functional layer may include at least one of an electron transmission layer, a hole transmission layer, an electron injection layer, a hole injection layer, and an electron blocking layer. Thus, the luminance efficiency is better, and the usage effect of the obtained organic electroluminescent device is better.

According to the embodiment of the disclosure, no special limits are made to the material that forms the second electrode, which may be any material adapted to form the second electrode in the art, for example, a transparent conductive oxide (for example, indium tin oxide, zinc tin oxide, indium zinc oxide, aluminum-doped zinc oxide and so on), a metal (for example, copper, silver, aluminum and so on).

In another aspect of the disclosure, the disclosure provides an organic electroluminescent device. According to the embodiment of the disclosure, the organic electroluminescent device is manufactured by the aforementioned method. The inventor has found that, for the organic electroluminescent device, the number of bad bright dots is significantly reduced, the display effect and quality is notably improved, and the quality control grade is notably increased.

In another aspect of the disclosure, the disclosure provides an organic electroluminescent device. According to the embodiment of the disclosure, referring to FIG. 5, the organic electroluminescent device comprises: a first electrode 10; a second electrode 30 arranged opposite to the first electrode 10; an organic functional layer 20 arranged between the first electrode 10 and the second electrode 20, wherein in a sub-pixel unit corresponding to a bright dot, an insulating layer 40 is further arranged between the first electrode 10 and the organic functional layer 20. Thus, the insulating layer 40 may effectively block transmission of holes such that the sub-pixel unit corresponding to the bright dot will not emit the lights, that is to say, the bright dot is converted into a dark dot. Thus, for the organic electroluminescent device, the quality control grade is effectively increased, and the display effect is notably improved.

Those skilled in the art may understand that, FIG. 5 illustrates a structural schematic diagram of a cross section of the sub-pixel unit corresponding to the bright dot. A qualified sub-pixel unit is not provided with the insulating layer 40. In addition, no special limits are made to the number of sub-pixel units included in each pixel unit, for example, there are 3, 4, 5 or more sub-pixel units, specifically in a RGB color pattern, a RGBYW color pattern or other patterns.

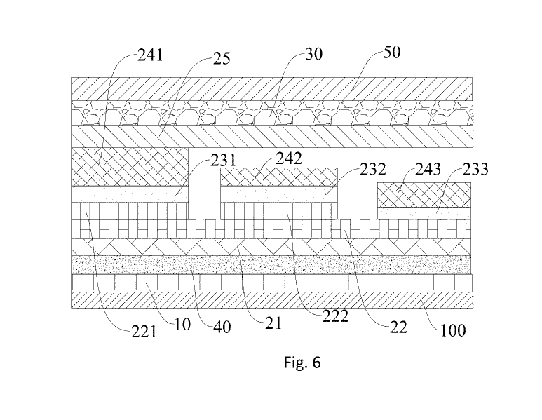

An organic electroluminescent device in a RGB color pattern is taken as an example below to explain a structure of a pixel unit of the organic electroluminescent device. In the example of the disclosure, referring to FIG. 6, the organic electroluminescent device comprises: a substrate 100, a first electrode 10, an insulating layer 40, a hole injection layer 21, a hole transmission layer 22, a first sub-hole transmission layer 221, a second sub-hole transmission layer 222, a first electron blocking layer 231, a second electron blocking layer 232, a third electron blocking layer 233, a red light emitting layer 241, a green light emitting layer 242, a blue light emitting layer 243, an electron transmission layer 25, a second electrode 30, and a coverage layer 50. In the pixel unit, due to the presence of the insulating layer 40, the holes cannot reach the light emitting layer from the first electrode, so the picture or information cannot be displayed all the time, that is to say, the bright dot is converted into a dark dot. Moreover, the covering layer is arranged to effectively eliminate stray light and enhance outgoing light, as well as provide a function of an excellent protection for the underlying second electrode or the other structures.

In another aspect of the disclosure, the disclosure provides a display apparatus. According to the embodiment of the disclosure, the display apparatus comprises the aforementioned electroluminescent display device. The inventor has found that, a probability that the bright dot badness occurs in the display apparatus is significantly reduced, and the display effect and quality is notably improved.

According to the embodiment of the disclosure, no special limits are made to the specific types of the display apparatus, which may be any apparatus or device having a display function in the art, for example, including but not limited to, a mobile phone, a tablet PC, a computer display, a game machine, a TV set, a display screen, a wearable device, or the other domestic appliance or household appliance having a display function.

Certainly, those skilled in the art may understand that, in addition to the aforementioned organic electroluminescent device, the display apparatus as set forth in the disclosure may further comprise necessary structures and components as owned by a conventional display apparatus. An explanation is made by taking the mobile phone as an example. In addition to the organic electroluminescent display device of the disclosure, it may further comprise a touch screen, a housing, a CPU, a camera module, a fingerprint recognition module, a sound processing system, and the other structures and components owned by a conventional mobile phone, which are not repeatedly described herein.

In the description of the disclosure, it should be understood that, an orientation or position relationship as donated by “center”, “longitudinal”, “transverse”, “length”, “width”, “thickness”, “above”, “below”, “front”, “back”, “left”, “right”, “vertical”, “horizontal”, “top”, “bottom”, “inside”, “outside”, “clockwise”, “anticlockwise”, “axial”, “radial”, “circumferential” is an orientation or position relationship based on the drawings, which is for the only purpose of conveniently describing the disclosure and simplifying the description, instead of indicating or implying that the denoted apparatus or element must have a particular orientation or be structured and operated in a particular orientation, and thus cannot be understood as a limit to the disclosure.

Besides, terms “first” and “second” are used only for a descriptive purpose instead of being understood as indicating or implying a relative significance or implicitly indicating the number of the denoted technical features. Thus, the feature defined by “first” or “second” can explicitly or implicitly include one or more said features. In the description of the disclosure, “more” means two or more than two, unless otherwise clearly defined.

In the disclosure, unless otherwise clearly specified and defined, “mounted”, “linked”, “connected”, “fixed” and other terms shall be understood in a broad sense, for example, fixedly connected, or detachably connected, or integrated; mechanically connected or electrically connected; directly connected or indirectly connected through an intermediation; inner communication between two elements or a mutual function relationship between two elements. For those skilled in the art, the specific meanings of the aforementioned terms in the disclosure can be understood in accordance with specific conditions.

In the disclosure, unless otherwise clearly specified and defined, the first feature “above” or “below” the second feature means a direct contact of the first and second features or an indirect contact of the first and second features through an intermediation. Further, the first feature “above”, “on” or “over” the second feature means that the first feature is right above or obliquely above the second feature, or only indicates that a level of the first feature is higher than that of the second feature. The first feature “below”, “under” or “beneath” the second feature means that the first feature is right below or obliquely below the second feature, or only indicates that a level of the first feature is less than that of the second feature.

Among the description of the Specification, a description with reference to “one embodiment”, “some embodiments”, “example”, “a specific example” or “some examples” means that a specific feature, structure, material or characteristic which is described by incorporating the embodiment or example is included in at least one embodiment or example of the disclosure. In the Specification, schematic expressions of the aforementioned terms are not necessarily directed to the same embodiment or example. Further, the described specific feature, structure, material or characteristic may be incorporated into any one or more embodiments or examples in a proper way. Besides, in case of no mutual contradiction, those skilled in the art can incorporate and combine different embodiments or examples as well as features of different embodiments or examples as described in the Specification.

Although embodiments of the disclosure have been illustrated and described above, it can be understood that the aforementioned embodiments are exemplary and cannot be understood as a limit to the disclosure. Those skilled in the art can alter, modify, replace and vary the aforementioned embodiments within the scope of the disclosure.

What is claimed is:

1. A method of restoring a bright dot of an organic electroluminescent device, comprising:
blocking transmission of holes or electrons in a sub-pixel unit corresponding to the bright dot.

2. The method according to claim 1, wherein the blocking transmission of holes or electrons in the sub-pixel unit corresponding to the bright dot is implemented by insulation between a first electrode and an organic functional layer in the sub-pixel unit corresponding to the bright dot.

3. The method according to claim 2, wherein the step of blocking comprises:
determining a coordinate of the sub-pixel unit corresponding to the bright dot on a base, wherein the base comprises a substrate and the first electrode arranged on a side of the substrate; and
forming an insulating layer at a position corresponding to the coordinate, the insulating layer covering the first electrode.

4. The method according to claim 3, wherein the coordinate of the sub-pixel unit corresponding to the bright dot is determined by automatic optical inspection.

5. The method according to claim 3, wherein a material that forms the insulating layer comprises polyimide.

6. A method of manufacturing an organic electroluminescent device, comprising a step of restoring a bright dot by the method according to claim 1.

7. The method according to claim 6, wherein the blocking transmission of holes or electrons in the sub-pixel unit corresponding to the bright dot is implemented by insulation between a first electrode and an organic functional layer in the sub-pixel unit corresponding to the bright dot.

8. The method according to claim 7, wherein the step of blocking comprises:
determining a coordinate of the sub-pixel unit corresponding to the bright dot on a base, wherein the base comprises a substrate and the first electrode arranged on a side of the substrate; and
forming an insulating layer at a position corresponding to the coordinate, the insulating layer covering the first electrode.

9. The method according to claim 8, wherein the coordinate of the sub-pixel unit corresponding to the bright dot is determined by automatic optical inspection.

10. The method according to claim 8, wherein a material that forms the insulating layer comprises polyimide.

11. The method according to claim 6, wherein the step of restoring comprises:
forming a first electrode on the substrate to obtain a base;
determining a coordinate of a sub-pixel unit corresponding to the bright dot on the base;
forming an insulating layer at a position corresponding to the coordinate, the insulating layer covering the first electrode; and
forming an organic functional layer and a second electrode in sequence on a side of the first electrode and the insulating layer far away from the substrate.

12. An organic electroluminescent device, comprising:
a first electrode;
a second electrode arranged opposite to the first electrode; and
an organic functional layer arranged between the first electrode and the second electrode,
wherein in a sub-pixel unit corresponding to a bright dot, an insulating layer is further arranged between the first electrode and the organic functional layer.

13. A display apparatus, comprising the organic electroluminescent device according to claim 12.
